(19) United States
(12) Patent Application Publication
(10) Pub. No.: US 2022/0364798 A1
(43) Pub. Date: Nov. 17, 2022

(54) HEAT DISSIPATION MODULE AND MANUFACTURING METHOD THEREOF

(71) Applicant: TAIWAN MICROLOOPS CORP., New Taipei City (TW)

(72) Inventor: Chun-Hung LIN, New Taipei City (TW)

(21) Appl. No.: 17/322,359

(22) Filed: May 17, 2021

(51) Int. Cl. F28F 1/30; F28D 15/02; B23P 15/26; H05K 7/20

(52) U.S. Cl. CPC F28F 1/30; F28D 15/02; B23P 15/26; H05K 7/2039; H05K 7/20336; B23P 2700/09

(57) ABSTRACT

The disclosure relates to a heat dissipation module and a manufacturing method thereof. The heat dissipation module includes a heat pipe, multiple heat dissipation fins and multiple rings. The heat pipe has a peripheral wall. Each heat dissipation fin has a through hole and an annular wall disposed on an outer edge of the through hole. The heat dissipation fins are adapted to sheathe the heat pipe in a spacedly stacked manner through the through hole. Each ring annularly is adapted to sheathe each annular wall in a compressive manner to embed and compressedly connect each annular wall to the peripheral wall. Therefore, efficiency of heat dissipation and structural strength of the heat dissipation structure are improved.

### BACKGROUND OF THE DISCLOSURE

### Technical Field

The disclosure relates to a heat dissipation structure including a heat pipe and multiple heat dissipation fins, particularly to a heat dissipation module and a manufacturing method thereof.

### Related Art

With the continuous increase of operating speed of electronic components, the generated heat is increasing accordingly. To solve the problem of high heat, the industry has developed various types of heat dissipation devices for heat dissipation. However, related-art heat dissipation devices still have drawbacks in practice.

A related-art heat dissipation device primarily includes a heat pipe, a thermo-conductive block and multiple heat dissipation fins. The heat pipe passes through both the thermo-conductive block and the heat dissipation fins. The thermo-conductive block is attached on an electronic component such as a central processing unit (CPU), so that the heat generated from the electronic component is dissipated to the outside through the heat dissipation fins and heat pipe.

In the process of inserting the heat pipe into the heat dissipation fins, however, the efficiency of heat dissipation and structural strength of the heat dissipation device are adversely affected if the heat dissipation fins cannot be firmly positioned on the heat pipe. Thus, how to firmly position the heat dissipation fins on the heat pipe is an important issue to be solved for the industry.

In view of this, the inventors have devoted themselves to the above-mentioned related-art art, researched intensively and cooperated with the application of science to try to solve the above-mentioned problems. Finally, the disclosure which is reasonable and effective to overcome the above drawbacks is provided.

### SUMMARY OF THE DISCLOSURE

The disclosure provides a heat dissipation module and a manufacturing method thereof, which utilize a ring to be adapted to sheathe the annular wall in a compressive manner to embed and compressedly connect the annular wall to the peripheral wall. As a result, efficiency of heat dissipation and structural strength of the heat dissipation structure are improved.

In an embodiment of the disclosure, the disclosure provides a heat dissipation module, which includes a heat pipe, multiple heat dissipation fins and multiple rings. The heat pipe has a peripheral wall. Each heat dissipation fin has a through hole and an annular wall disposed on an outer edge of the through hole. The heat dissipation fins are adapted to sheathe the heat pipe in a spacedly stacked manner through the through hole. Each ring is adapted to sheathe each annular wall in a compressive manner to embed and compressedly connect each annular wall to the peripheral wall.

In an embodiment of the disclosure, the disclosure provides a manufacturing method of a heat dissipation module, which includes the steps of: a) providing a heat dissipation fin having a through hole and an annular wall formed on an outer edge of the through hole; b) providing a ring, the ring being a conic ring, the conic ring having an upper bottom opening and a lower bottom opening, an inner diameter of the upper bottom opening being less than an outer diameter of the annular wall, an inner diameter of the lower bottom opening being greater than an outer diameter of the annular wall, and the conic ring being adapted to sheathe the annular wall; c) providing a heat pipe having a peripheral wall, and sheathing the heat pipe with the heat dissipation fin tightly through the through hole; and d) providing a pressing jig for downwardly pressing the conic ring to be adapted to compressedly sheathe the annular wall until the annular wall being pressed and deformed by the ring to be embedded and connected compressedly to the peripheral wall.

In an embodiment of the disclosure, the disclosure provides a method for manufacturing a heat dissipation module, which includes the steps of: e) providing a heat dissipation fin having a through hole and an annular wall formed on an outer edge of the through hole; f) providing a ring, the ring having a cylindrical ring, and the cylindrical ring being adapted to compressedly sheathe outside the annular wall; g) providing a heat pipe having a peripheral wall, and sheathing the heat pipe with the heat dissipation fin tightly through the through hole; and h) providing a pressing jig for inwardly pressing the cylindrical ring until the annular wall being pressed and deformed by the ring to be embedded and connected compressedly to the peripheral wall.

As a result, when the heat dissipation fin is adapted to sheathe tightly outside the heat pipe through the through hole, the heat pipe may be slightly stretch the annular wall to make the heat dissipation fin be unable to be firmly positioned on the heat pipe. After the ring is adapted to sheathe the annular wall in a compressive manner, the annular wall is pressed by the ring to be embedded and connected tightly to the peripheral wall. This makes the annular wall be closely in thermal contact with the peripheral wall for the heat of the heat pipe to be rapidly transferred to the heat dissipation fin. The heat dissipation fin may also be firmly positioned on the heat pipe. Thus, efficiency of heat dissipation and structural strength of the heat dissipation module are improved.

### BRIEF DESCRIPTION OF THE DRAWINGS

FIG. 1 is a flowchart of the manufacturing method of the heat dissipation module of the disclosure;

FIG. 2 is an exploded view of the heat dissipation fin and the ring of the disclosure;

FIG. 3 is a perspective view of the disclosure, which shows the heat dissipation fin is being passed by the heat pipe;

FIG. 4 is a cross-sectional view of the disclosure, which shows the heat dissipation fin is being passed by the heat pipe;

FIG. 5 is a perspective view of the disclosure, which shows the heat dissipation fins are being passed by the heat pipe one by one;

FIG. 6 is a cross-sectional view of the disclosure, which shows the heat dissipation fins are being passed by the heat pipe one by one;

FIG. 7 is a perspective view of the disclosure, which shows the heat dissipation fins have been passed by the heat pipe;

FIG. 8 is a cross-sectional view of the disclosure, which shows the heat dissipation fins have been passed by the heat pipe;

FIG. 9 is an enlarged view of the dotted-line frame in FIG. 8;

FIG. 10 is a flowchart of another embodiment of the method for manufacturing the heat dissipation module of the disclosure;

FIG. 11 is an exploded view of the heat dissipation fin and the ring in another embodiment of the disclosure;

FIG. 12 is a cross-sectional view of another embodiment of the disclosure, which shows the heat dissipation fin is being passed by the heat pipe;

FIG. 13 is a cross-sectional view of another embodiment of the disclosure, which shows the heat dissipation fins have been passed by the heat pipe; and

FIG. 14 is a cross-sectional view of another embodiment of the disclosure, which shows the pressing jig is inward pressing the cylindrical ring.

### DETAILED DESCRIPTION OF THE DISCLOSURE

To further disclose the features and technical contents of the disclosure, please refer to the following description and the drawings. However, the drawings are used for reference and description only, not for limitation to the disclosure.

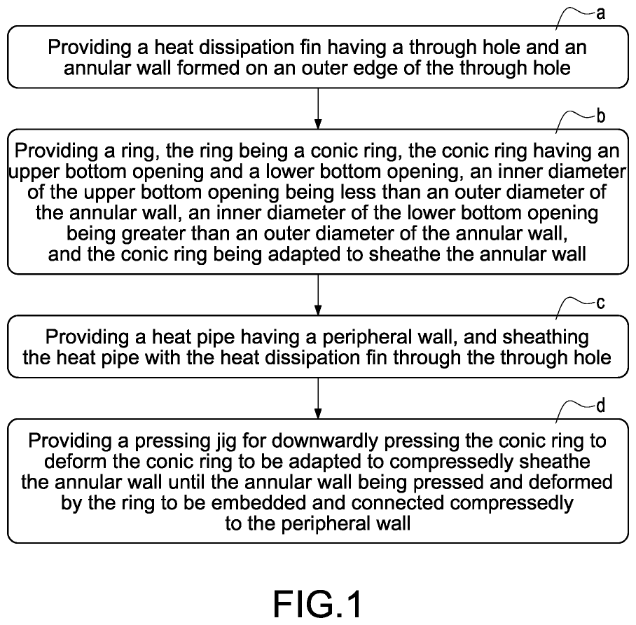

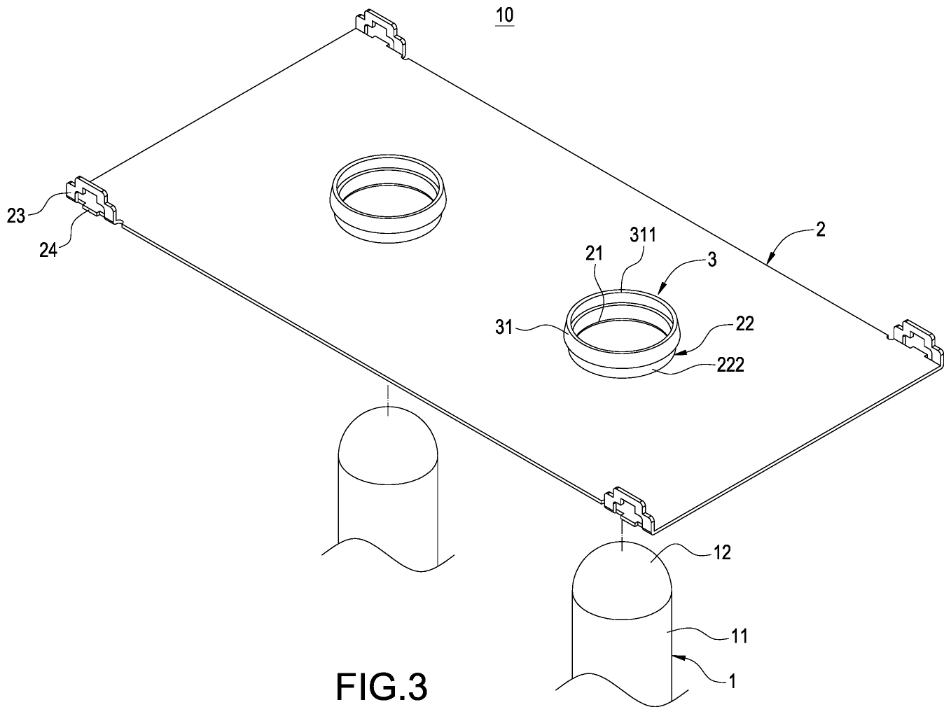

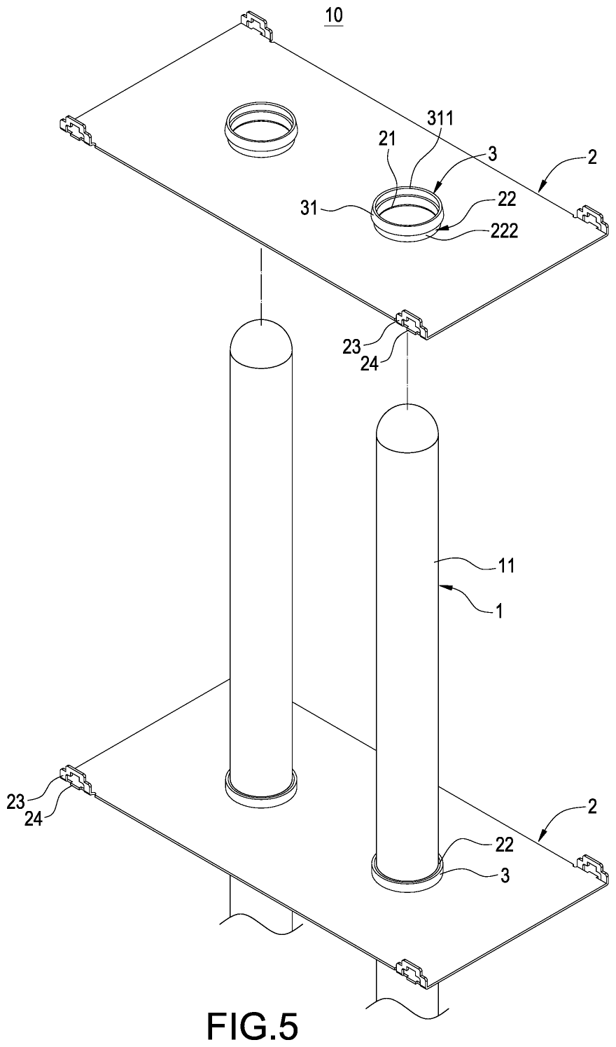

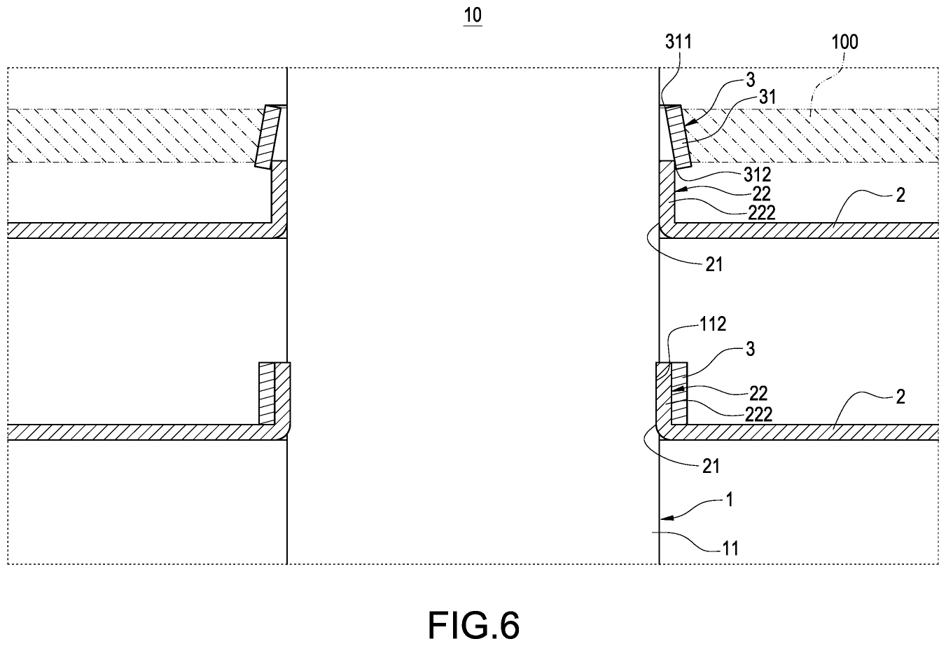

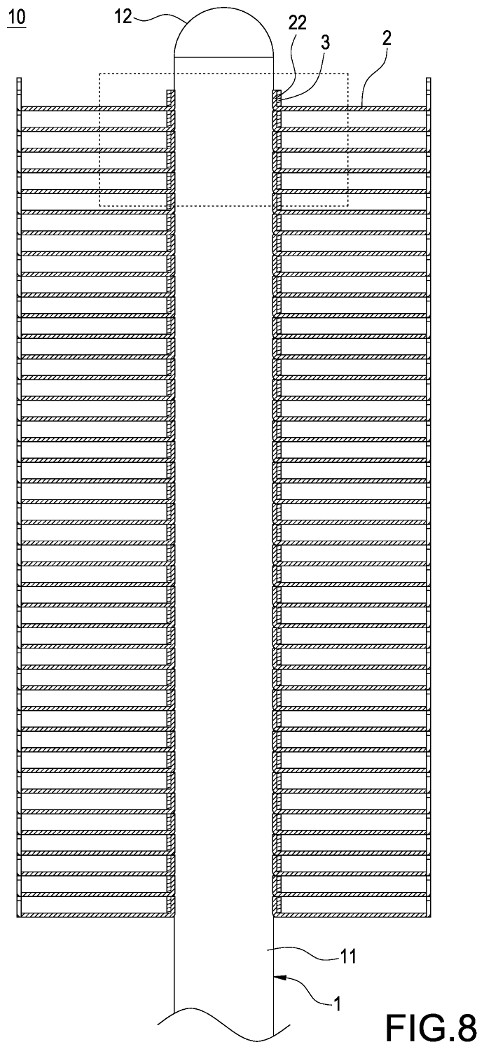

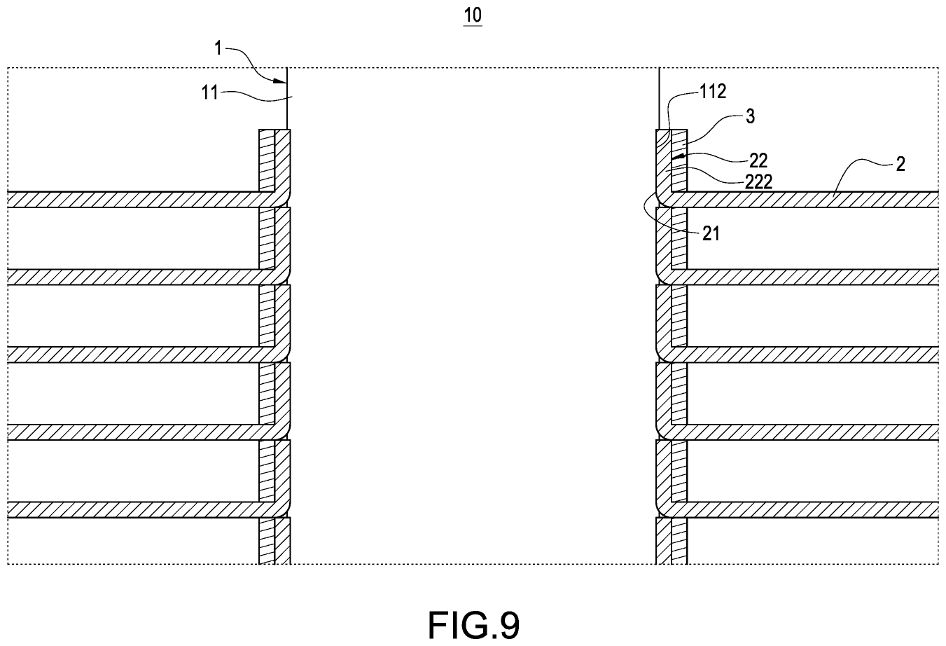

Please refer to FIGS. 1-9. The disclosure provides a heat dissipation module and a manufacturing method thereof. The heat dissipation module 10 includes one or more heat pipes 1, a plurality of heat dissipation fins 2 and a plurality of rings 3.

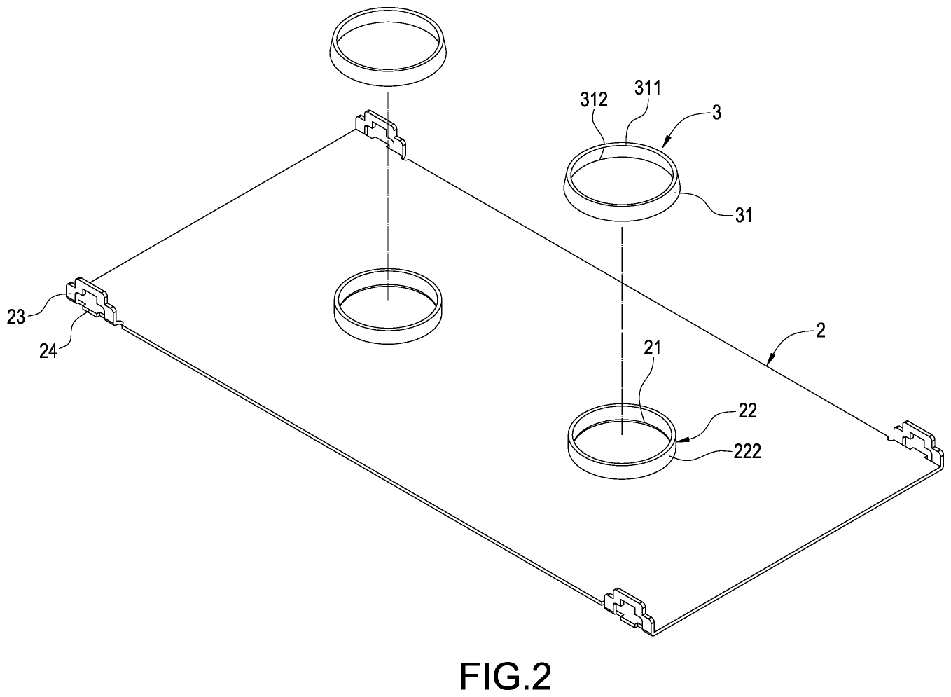

As show in FIG. 1, this figure shows the steps of the manufacturing method of the heat dissipation module 10. The details are described as follows. First, as shown in the step a) of FIG. 1 and FIG. 2, a heat dissipation fin 2 is provided, the heat dissipation fin 2 has a through hole 21 and an annular wall 22 formed on an outer edge of the through hole 21. In this embodiment, a number of the through hole 21 and the annular wall 22 of the heat dissipation fin 2 respectively is, but not limited to, multiple.

Secondly, as shown in the step b) of FIG. 1 and FIGS. 2-4, a ring 3 is provided. The ring 3 is a conic ring 31. The conic ring 31 has an upper bottom opening 311 and a lower bottom opening 312. The upper bottom opening 311 and the lower bottom opening 312 are arranged on an upper side and a lower side of the conic ring 31 respectively. An inner diameter S2 of the upper bottom opening 311 is less than an outer diameter W2 of the annular wall 22, and an inner diameter S3 of the lower bottom opening 312 is greater than an outer diameter W2 of the annular wall 22. The conic ring 31 is adapted to sheathe the annular wall 22. In other words, the annular wall 22 is sheathed with the conic ring 31.

In detail, in the step b), an inner diameter of the conic ring 31 tapers from the lower bottom opening 312 to the upper bottom opening 311. The heat pipe 1 has a top 12. The upper bottom opening 311 is more adjacent to the top 12 than the lower opening 312.

The size difference between the inner diameter S2 of the upper bottom opening 311 and the outer diameter W2 of the annular wall 22 is between 0.05 mm and 0.1 mm. The size difference between the inner diameter S3 of the lower bottom opening 312 and the outer diameter W2 of the annular wall 22 is between 0.05 mm and 0.1 mm. In this embodiment, a number of the ring 3 is, but not limited to, multiple.

In addition, a hardness of the ring 3 is greater than a hardness of the annular wall 22. For example, the annular wall 22 is made of copper and the ring 3 is made of a material with the hardness higher than that of copper, such as aluminum, iron, or stainless steel, etc.

Thirdly, as shown in the step c) of FIG. 1 and FIGS. 3-6, a heat pipe 1 having a peripheral wall 11 is provided. The heat dissipation fin 2 is adapted to tightly sheathe the heat pipe 1 through the through hole 21. In other words, the heat pipe 1 is compressedly sheathed with the heat dissipation fin 2. In this embodiment, a number of the heat pipe 1 is, but not limited to, multiple.

Furthermore, in the step c), the heat dissipation fin 2 is adapted to sheathe the heat pipe 1 from the top 12. The annular wall 22 is a cylindrical annular wall 222. An inner diameter S1 of the cylindrical annular wall 222 is less than an outer diameter W1 of the heat pipe 1. The size difference between the inner diameter S1 of the cylindrical annular wall 222 and the outer diameter W1 of the heat pipe 1 is between 0.05 mm and 0.1 mm, so that the cylindrical annular wall 222 compressedly connects the peripheral wall 11. For example, when the outer diameter W1 of the heat pipe 1 is 8 mm, the inner diameter S1 of the cylindrical annular wall 222 is about 7.9 mm, but not limited to this.

Fourthly, as shown in the step d) of FIG. 1 and FIGS. 5-9, a pressing jig 100 is provided. The pressing jig 100 is used for downwardly pressing the conic ring 31 to deform the conic ring 31 to be adapted to compressedly sheathe the annular wall 22 until the annular wall 22 is pressed and deformed by the ring 3 to be embedded and connected compressedly to the peripheral wall 11.

In detail, in the step d), the ring 3 is adapted to sheathe the annular wall 22 in a compressive manner to make the peripheral wall 11 be pressed by the annular wall 22 to form a cylindrical annular groove 112. The cylindrical annular wall 222 is embedded into the cylindrical annular groove 112 in a compressive manner to embed and connect compressedly the annular walls 22 to the peripheral wall 11.

In addition, in this embodiment, a number of the heat dissipation fin 2 is multiple. The heat dissipation fins 2 are adapted to sheathe the heat pipe 1 in a spacedly stacked manner through each through hole 21. An outer periphery of each heat dissipation fin 2 is upwardly extended with multiple inverted T-shape connecting sheets 23 meshed with each other. The outer periphery of each heat dissipation fin 2 is outwardly extended with multiple latches 24 inserted respectively between adjacent two of the inverted T-shape connecting sheets 23. This makes the heat dissipation fins 2 firmly stacked and connected together.

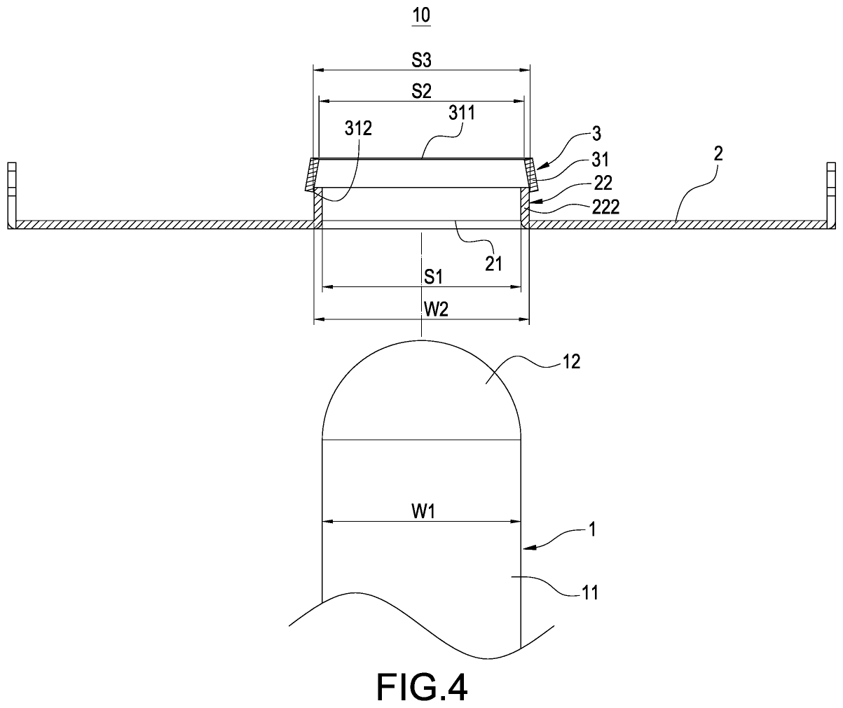

Please refer to FIGS. 4-9, which show the using status of the heat dissipation module 10 of the disclosure. When the heat dissipation fin 2 is adapted to tightly sheathe the heat pipe 1 through the through hole 21, the heat pipe 1 may slightly stretch the annular wall 22 to make the heat dissipation fin 2 be unable to be firmly positioned on the heat pipe 1. After the ring 3 is adapted to sheathe the annular wall 22 in a compressive manner, the annular wall 22 is pressed by the ring 3 to be embedded and connected compressedly to the peripheral wall 11. This makes the annular wall 22 be closely in thermal contact with the peripheral wall 11 for the heat of the heat pipe 1 to be rapidly transferred to the heat dissipation fin 2. The heat dissipation fin 2 may also be firmly positioned on the heat pipe 1. Thus, efficiency of heat dissipation and structural strength of the heat dissipation module 10 are improved.

In addition, when the annular wall 22 is pressed toward the heat pipe 1 by the ring 3, a part of the annular wall 22 is securely embedded into the peripheral wall 11 of the heat pipe 1 and the part of the annular wall 22 compressedly connects the peripheral wall 11 of the heat pipe 1. This further improves efficiency of heat dissipation and structural strength of the heat dissipation module 10.

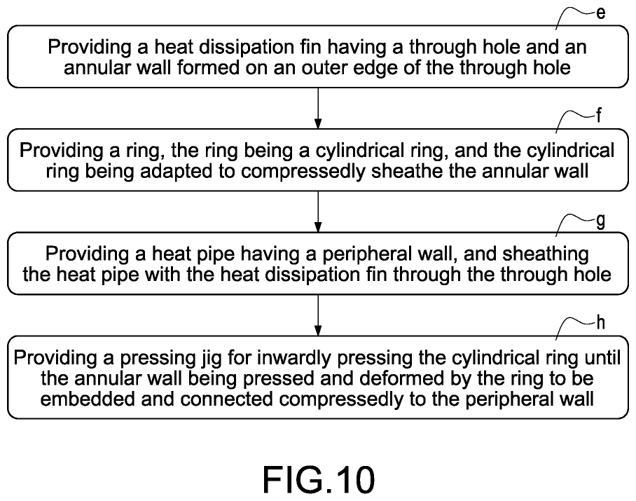

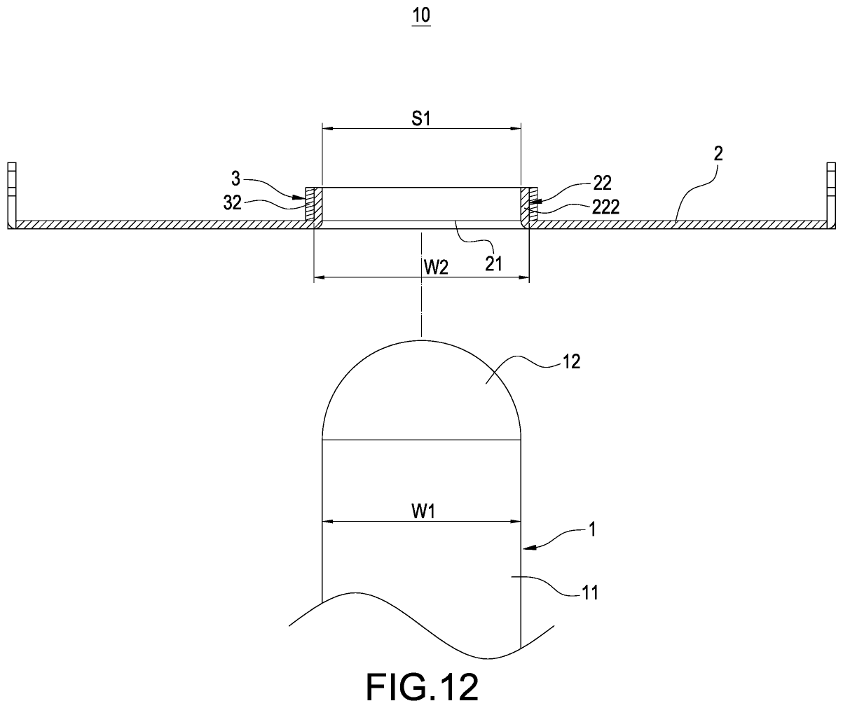

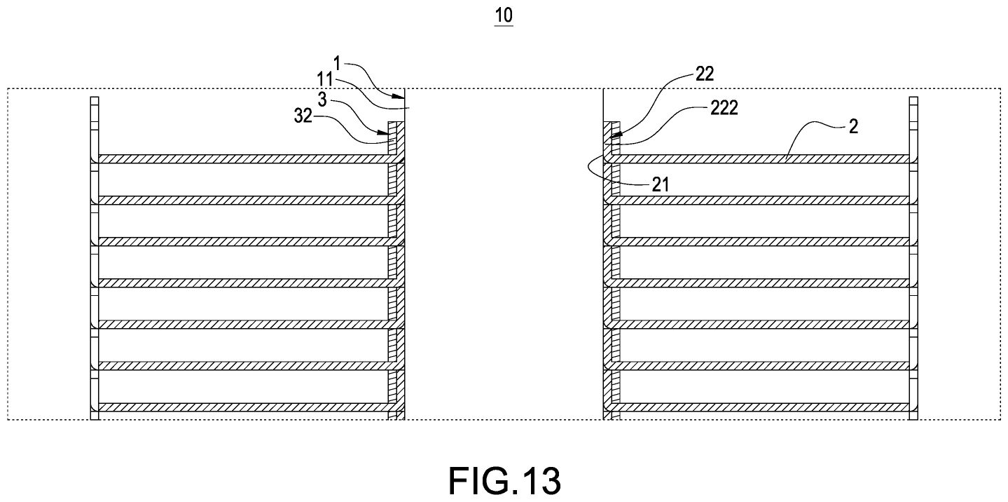

Please refer to FIGS. 10-14, which show another embodiment of the manufacturing method of the heat dissipation module 10. As shown in FIG. 10, the steps of another embodiment of the manufacturing method of the heat dissipation module 10 is described below.

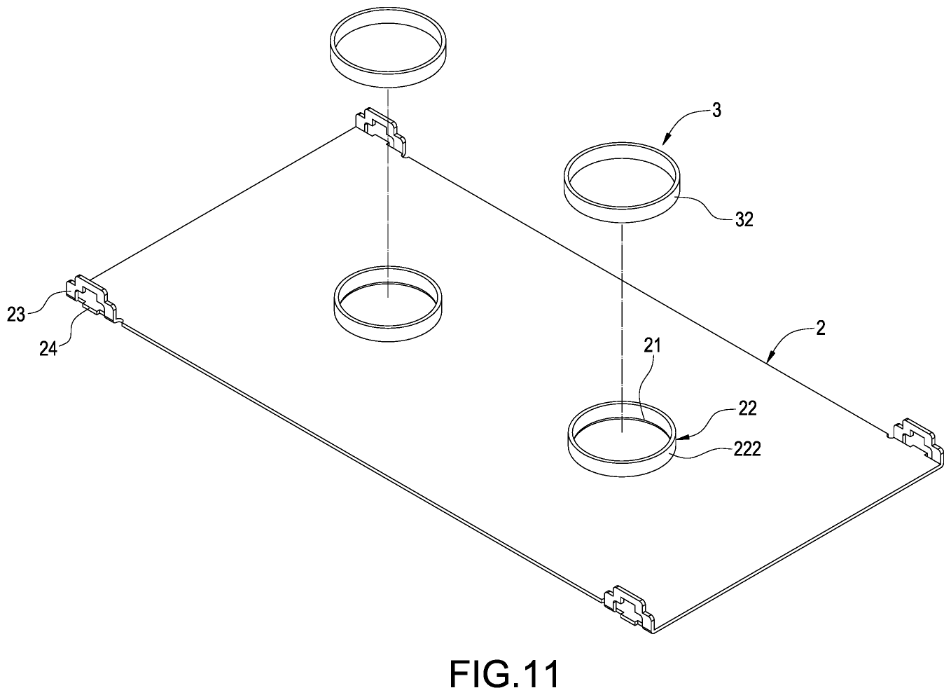

First, as shown in the step e) of FIG. 10 and FIG. 11, a heat dissipation fin 2 is provided. The heat dissipation fin 2 has a through hole 21 and an annular wall 22 formed on an outer edge of the through hole 21. In this embodiment, a number of the through hole 21 and the annular wall 22 of the heat dissipation fin 2 respectively is, but not limited to, multiple.

Secondly, as shown in the step f) of FIG. 10 and FIGS. 11-12, a ring 3 is provided. The ring 3 is a cylindrical ring 32. The cylindrical ring 32 is adapted to tightly sheathe the annular wall 22. In other words, the annular wall 22 is compressedly sheathed with the cylindrical ring 32.

The size difference between the inner diameter of the cylindrical ring 32 and the outer diameter W2 of the annular wall 22 is between 0.05 mm and 0.1 mm. In this embodiment, a number of the ring 3 is, but not limited to, multiple.

In addition, a hardness of the ring 3 is greater than a hardness of the annular wall 22. For example, the annular wall 22 is made of copper and the ring 3 is made of a material with the hardness higher than that of copper, such as aluminum, iron, or stainless steel, etc.

Thirdly, as shown in the step g) of FIG. 10 and FIGS. 12-13, a heat pipe 1 having a peripheral wall 11 is provided. The heat dissipation fin 2 is adapted to tightly sheathe the heat pipe 1 through the through hole 21. In other words, the heat pipe 1 is compressedly sheathed with the heat dissipation fin 2. In this embodiment, a number of the heat pipe 1 is, but not limited to, multiple.

Besides, in the step g), the annular wall 22 is a cylindrical annular wall 222. An inner diameter S1 of the cylindrical annular wall 222 is less than an outer diameter W1 of the heat pipe 1. The size difference between the inner diameter S1 of the cylindrical annular wall 222 and the outer diameter W1 of the heat pipe 1 is between 0.05 mm and 0.1 mm, so that the cylindrical annular wall 222 is connected compressedly to the peripheral wall 11. For example, when the outer diameter W1 of the heat pipe 1 is 8 mm, the inner diameter S1 of the cylindrical annular wall 222 is about 7.9 mm, but not limited to this.

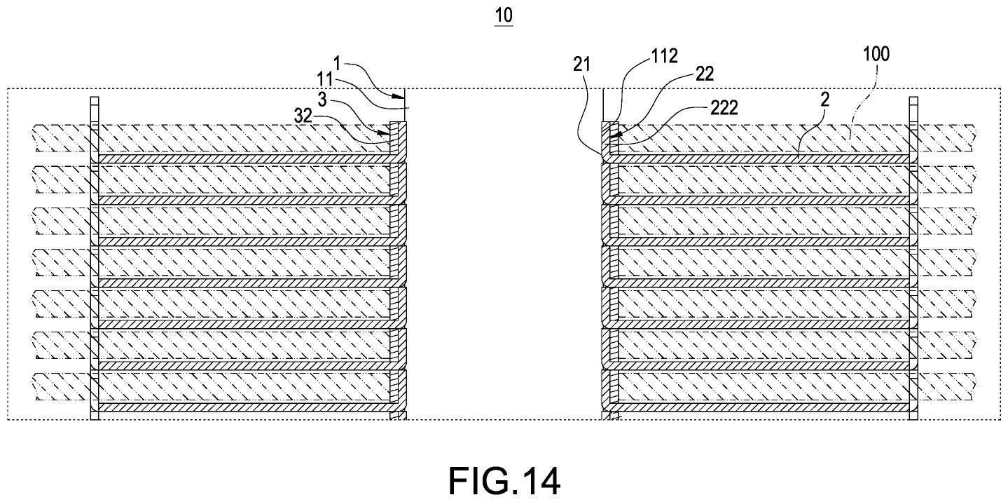

Fourthly, as shown in the step h) of FIG. 10 and FIG. 14, a pressing jig 100 is provided for inwardly pressing the cylindrical ring 32 until the annular wall 22 is pressed and deformed by the ring 3 to be embedded and connected compressedly to the peripheral wall 11.

In detail, in the step h), the ring 3 is adapted to sheathe the annular wall 22 in a compressive manner to make the peripheral wall 11 be pressed by the annular wall 22 to form a cylindrical annular groove 112. The cylindrical annular wall 222 is embedded into the cylindrical annular groove 112 in a compressive manner to make the annular walls 22 be embedded and connected compressedly to the peripheral wall 11.

In addition, in this embodiment, a number of the heat dissipation fin 2 is multiple. The heat dissipation fins 2 are adapted to sheathe the heat pipe 1 in a spacedly stacked manner through each through hole 21. An outer periphery of each heat dissipation fin 2 is upwardly extended with multiple inverted T-shape connecting sheets 23 meshed with each other. The outer periphery of each heat dissipation fin 2 is outwardly extended with multiple latches 24 inserted respectively between adjacent two of the inverted T-shape connecting sheets 23. This makes the heat dissipation fins 2 be firmly stacked and connected together.

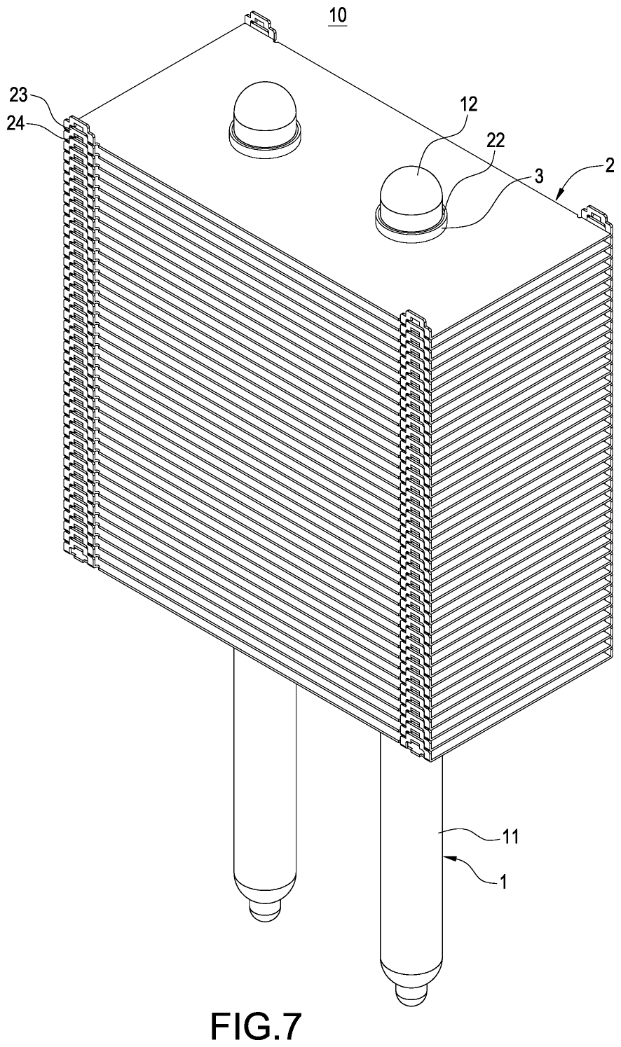

Thereby, the heat dissipation module 10 of FIGS. 7-9 may be made by the steps e) through h) of FIG. 10. Accordingly, the heat dissipation module 10 may be made by either the steps a) through d) or the steps e) through h).

It will be appreciated by persons skilled in the art that the above embodiments have been described by way of example only and not in any limitative sense, and that various alterations and modifications are possible without departure from the scope of the disclosure as defined by the appended claims.

What is claimed is:

1. A heat dissipation module comprising:
a heat pipe, comprising a peripheral wall;
a plurality of heat dissipation fins, each comprising a through hole and an annular wall disposed on an outer edge of the through hole, and the heat dissipation fins adapted to sheathe the heat pipe in a spacedly stacked manner through the through hole; and
a plurality of rings, each adapted to sheathe each annular wall in a compressive manner to embed and compressedly connect each annular wall to the peripheral wall.

2. The heat dissipation module of claim 1, wherein each annular wall comprises a cylindrical annular wall, a plurality of cylindrical annular grooves is disposed on the peripheral wall, and each cylindrical annular wall is embedded in each cylindrical annular groove in a compressive manner.

3. The heat dissipation module of claim 1, wherein an outer periphery of each heat dissipation fin is upwardly extended with a plurality of inverted T-shape connecting sheets meshed with each other and is outwardly extended with a plurality of latches inserted respectively between each two of the inverted T-shape connecting sheets adjacent to each other, and a hardness of each ring is greater than a hardness of each annular wall.

4. A manufacturing method of a heat dissipation module, the manufacturing method comprising:
a) providing a heat dissipation fin comprising a through hole and an annular wall formed on an outer edge of the through hole;
b) providing a ring, wherein the ring comprises a conic ring, the conic ring comprises an upper bottom opening and a lower bottom opening, an inner diameter of the upper bottom opening is less than an outer diameter of the annular wall, an inner diameter of the lower bottom opening is greater than an outer diameter of the annular wall, and the conic ring is adapted to sheathe the annular wall;
c) providing a heat pipe comprising a peripheral wall, and sheathing the heat pipe with the heat dissipation fin through the through hole; and
d) providing a pressing jig for downwardly pressing the conic ring to deform the conic ring to be adapted to compressedly sheathe the annular wall until the annular wall being pressed and deformed by the ring to be embedded and connected compressedly to the peripheral wall.

5. The manufacturing method of claim 4, wherein in the step c), the annular wall comprises a cylindrical annular wall, an inner diameter of the cylindrical annular wall is less than an outer diameter of the heat pipe, and a size difference between the inner diameter of the cylindrical annular wall and the outer diameter of the heat pipe is between 0.05 mm and 0.1 mm to connect compressedly the cylindrical annular wall to the peripheral wall.

6. The manufacturing method of claim 5, wherein in the step b), an inner diameter of the conic ring tapers from the lower bottom opening to the upper bottom opening, the heat pipe comprises a top, and the upper bottom opening is arranged more adjacent to the top than the lower bottom opening.

7. The manufacturing method of claim 6, wherein in the step d), the peripheral wall is formed with a cylindrical annular groove, and the cylindrical annular wall is embedded into the cylindrical annular groove in a compressive manner.

8. A manufacturing method of a heat dissipation module, the manufacturing method comprising:
e) providing a heat dissipation fin comprising a through hole and an annular wall formed on an outer edge of the through hole;
f) providing a ring, wherein the ring comprises a cylindrical ring, and the cylindrical ring is adapted to compressedly sheathe outside the annular wall;
g) providing a heat pipe comprising a peripheral wall, and sheathing the heat pipe with the heat dissipation fin through the through hole; and
h) providing a pressing jig for inwardly pressing the cylindrical ring until the annular wall being pressed and deformed by the ring to be embedded and connected compressedly to the peripheral wall.

9. The manufacturing method of claim 8, wherein in the step g), the annular wall comprises a cylindrical annular wall, an inner diameter of the cylindrical annular wall is less than an outer diameter of the heat pipe, and a size difference between the inner diameter of the cylindrical annular wall and the outer diameter of the heat pipe is between 0.05 mm and 0.1 mm to connect compressedly the cylindrical annular wall to the peripheral wall.

10. The manufacturing method of claim 9, wherein in the step g), the peripheral wall is formed with a cylindrical annular groove, and the cylindrical annular wall is embedded into the cylindrical annular groove in a compressive manner.
